(19) United States
(12) Patent Application Publication
(10) Pub. No.: US 2025/0149520 A1
(43) Pub. Date: May 8, 2025

(54) SEMICONDUCTOR PACKAGE

(71) Applicant: Samsung Electronics Co., Ltd., Suwon-si (KR)

(72) Inventors: Junghoon Kang, Suwon-si (KR); Daegon Kim, Suwon-si (KR)

(21) Appl. No.: 18/780,675

(22) Filed: Jul. 23, 2024

(30) Foreign Application Priority Data
Nov. 6, 2023 (KR) 10-2023-0151941

(51) Int. Cl. H01L 25/18; G02B 6/12; H01L 23/00; H01L 23/31; H01L 23/48; H01L 23/538; H01L 27/144

(52) U.S. Cl. CPC H01L 25/167; G02B 6/12004; H01L 23/481; H01L 24/16; H01L 24/32; H01L 24/73; H01L 2224/32225; H01L 2224/73253

(57) ABSTRACT

A semiconductor package including a package substrate, a plurality of chiplets located on the package substrate, the plurality of chiplets including a photonics chip and a semiconductor chip located on the photonics chip, and a plurality of photonics bridge chips located on the package substrate. The plurality of chiplets are spaced apart from each other in a horizontal direction, and each of the plurality of photonics bridge chips is located between the plurality of chiplets.

### CROSS-REFERENCE TO RELATED APPLICATION

This application is based on and claims priority under 35 U.S.C. § 119 to Korean Patent Application No. 10-2023-0151941, filed on Nov. 6, 2023, in the Korean Intellectual Property Office, the disclosure of which is incorporated by reference herein in its entirety.

### BACKGROUND

Aspects of the inventive concept relate to a semiconductor package and a method of manufacturing the same, and more specifically, to a semiconductor package including an optical integrated circuit chip.

The advantages of semiconductor packages have been increasingly used to improve the functions of electronic devices and integrate constituent components. In a semiconductor package, various integrated circuits, such as memory chips or logic chips, are mounted on a package substrate. With the recent increase in data traffic in data centers and communication infrastructures, research on semiconductor packages including optical integrated circuits has been ongoing.

### SUMMARY

Aspects of the inventive concept provide semiconductor packages including miniaturized photonics chips.

One aspect of the inventive concept provides semiconductor packages that are easy to test.

The problems to be solved by the technical spirit according to aspects of the inventive concept are not limited to the problems mentioned above, and other problems not mentioned will be clearly understood by those skilled in the art from the following description.

According to an aspect of the inventive concept, there is provided a semiconductor package including a package substrate, a plurality of chiplets located on the package substrate, the plurality of chiplets including a photonics chip and a semiconductor chip located on the photonics chip, and a plurality of photonics bridge chips located on the package substrate, wherein the plurality of chiplets are spaced apart from each other in a horizontal direction, and each of the plurality of photonics bridge chips is located between the plurality of chiplets.

According to another aspect of the inventive concept, there is provided a semiconductor package including a package substrate, a plurality of chiplets located on the package substrate, the plurality of chiplets including a photonics chip and a semiconductor chip located on the photonics chip, and a plurality of photonics bridge chips located on the package substrate and each including a bridge waveguide and a test waveguide disposed at the same vertical level, wherein the plurality of chiplets are spaced apart in a horizontal direction and arranged in a matrix on the package substrate, each of the plurality of photonics bridge chips is located between the plurality of chiplets, and the bridge waveguides of at least some of the plurality of photonics bridge chips face the bridge waveguides of other photonics bridge chips.

According to another aspect of the inventive concept, there is provided a a package substrate, an external connection terminal located at a bottom of the package substrate, a plurality of chiplets located on the package substrate, the plurality of chiplets including a photonics chip and a semiconductor chip located on the photonics chip, a plurality of photonics bridge chips located on the package substrate and each including a bridge waveguide and a test waveguide disposed at the same vertical level, and a transparent encapsulant located between the plurality of chiplets and the plurality of photonics bridge chips, wherein the plurality of chiplets are spaced apart from each other in a horizontal direction, each of the plurality of photonics bridge chips is located between the plurality of chiplets, and the bridge waveguide and the test waveguide are optically connected through a tunable coupler.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view taken along line A-A′ of the semiconductor package of FIG. 1;

FIG. 3 is an enlarged schematic cross-sectional view of portion EX1 of the semiconductor package of FIG. 2;

FIG. 4 is a schematic plan view of portion EX1 of the semiconductor package of FIG. 2;

FIG. 5 is a schematic cross-sectional view taken along line B-B′ of the semiconductor package of FIG. 4;

FIG. 6 is a schematic cross-sectional view of a semiconductor package, taken along a line the same as the line B-B′ of FIG. 4, according to an embodiment.

FIG. 7 is a schematic cross-sectional view of a semiconductor package, taken along a line the same as the line A-A′ of FIG. 1, according to an embodiment;

FIG. 8 is a schematic plan view of a semiconductor package according to an embodiment; and

FIG. 9 is a schematic cross-sectional view taken along line C-C′ of a semiconductor package of FIG. 8.

### DETAILED DESCRIPTION OF THE EMBODIMENTS

As the disclosure allows for various changes and numerous embodiments, some embodiments will be illustrated in the drawings and described in detail in the written description. However, the present embodiments are not intended to limit the specific disclosure form.

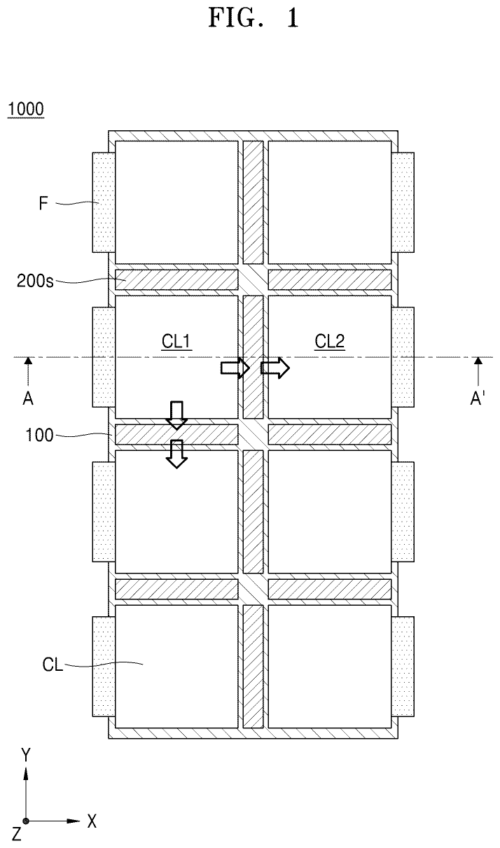

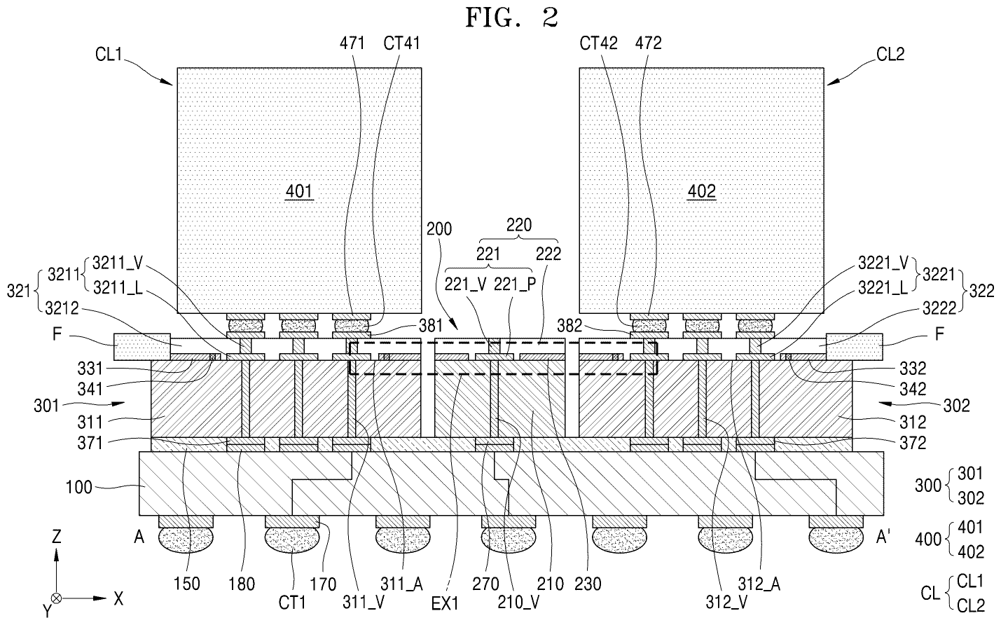

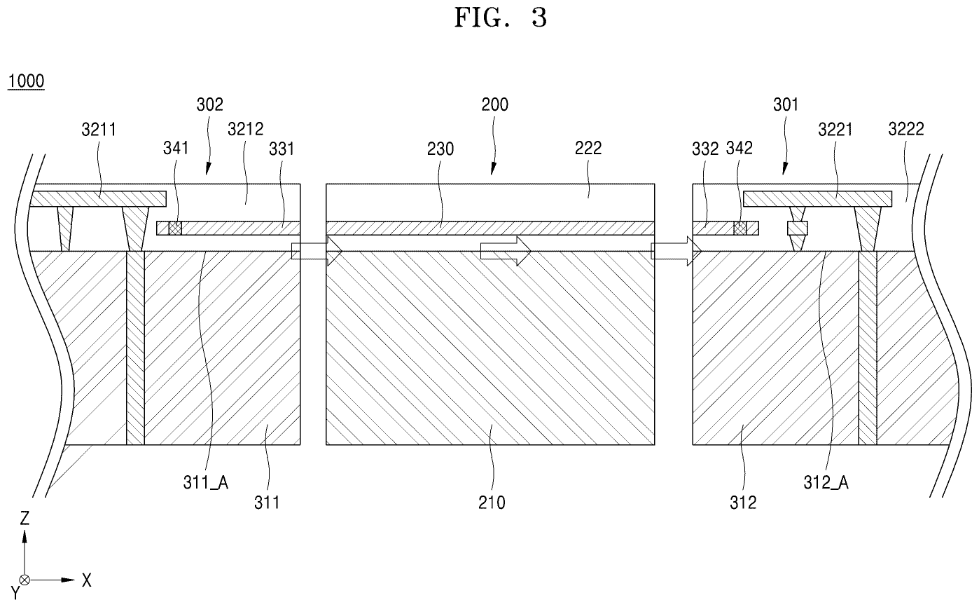

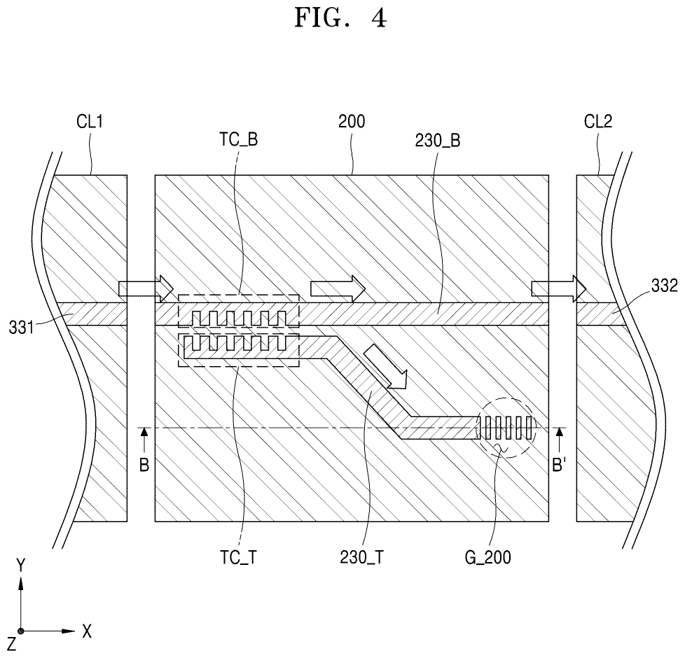

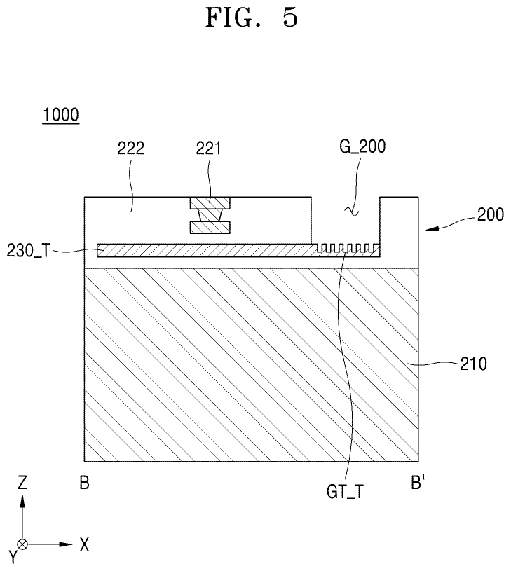

FIG. 1 is a schematic plan view of a semiconductor package 1000 according to an embodiment. FIG. 2 is a schematic cross-sectional view taken along line A-A′ of the semiconductor package 1000 of FIG. 1. FIG. 3 is an enlarged schematic cross-sectional view of portion EX1 of the semiconductor package 1000 of FIG. 2. FIG. 4 is a schematic plan view of portion EX1 of the semiconductor package 1000 of FIG. 2. FIG. 5 is a schematic cross-sectional view taken along line B-B′ of the semiconductor package 1000 of FIG. 4.

Referring to FIGS. 1 to 5, the semiconductor package 1000 may include a package substrate 100, a plurality of chiplets CL, and a plurality of photonics bridge chips 200s.

Hereinafter, unless specifically defined, a direction parallel to an upper surface of the package substrate 100 is defined as a first horizontal direction (X direction), a direction perpendicular to the upper surface of the package substrate 100 is defined as a vertical direction (Z direction), and a direction perpendicular to the first horizontal direction (X direction) and the vertical direction (Z direction) is defined as a second horizontal direction (Y direction). A direction that combines the first horizontal direction (X direction) and the second horizontal direction (Y direction) is defined as a horizontal direction.

The package substrate 100 of the semiconductor package 1000 may include, for example, a printed circuit board (PCB). The package substrate 100 may include a core insulating layer including at least one material selected from phenol resin, epoxy resin, and polyimide. For example, the core insulating layer may include at least one material selected from among polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package substrate 100 may include an upper pad 180 located on an upper surface of the core insulating layer and a lower pad 170 located on a lower surface of the core insulating layer. The upper pad 180 and the lower pad 170 may be parts of a circuit wiring patterned after coating copper foil (Cu foil) on the upper and lower surfaces of the core insulating layer. Specifically, the upper pad 180 and the lower pad 170 may be regions of the circuit wiring that are not covered by a solder resist layer and are exposed to the outside.

In some embodiments, the upper pad 180 and lower pad 170 may each include copper, nickel, stainless steel, or beryllium copper. An internal wiring may be formed within the package substrate 100 to electrically connect the upper pad 180 and the lower pad 170.

External connection terminals CT1 may be attached to the lower pad 170. The external connection terminals CT1 may be configured to electrically and physically connect between the package substrate 100 and an external device on which the package substrate 100 is mounted. The external connection terminals CT1 may be formed from, for example, solder balls or solder bumps.

However, the embodiment is not limited thereto, and the package substrate 100 may be mounted within a socket formed on an external device. For example, the package substrate 100 may be electrically and physically connected to an external device without the external connection terminals CT1.

In some embodiments, the package substrate 100 may be an interposer that includes a substrate and a redistribution layer formed on the substrate. For example, the substrate may include a glass substrate and a through-glass via, and the redistribution layer may include a redistribution structure and a redistribution insulating layer surrounding the redistribution structure.

Each of the plurality of chiplets CL of the semiconductor package 1000 may include a photonics chip 300 and a semiconductor chip 400. Each of the plurality of chiplets CL may include one photonics chip 300 and one semiconductor chip 400. For example, the number of photonics chips 300 and the semiconductor chips 400 included in the semiconductor package 1000 may be the same. For example, the photonics chip 300 and the semiconductor chip 400 may correspond one-to-one.

In some embodiments, the plurality of chiplets CL may be spaced apart in the horizontal direction and disposed on the package substrate 100. A plurality of chiplets CL may be arranged in a matrix. For example, the plurality of chiplets CL may be arranged to be spaced apart in the first horizontal direction (X direction) and the second horizontal direction (Y direction).

In FIG. 1, the plurality of chiplets CL are shown arranged in a 4×2 matrix, but the arrangement and number of the plurality of chiplets CL are not limited thereto.

The photonics chip 300 may convert an optical signal into an electrical signal. For example, the photonics chip 300 may include a photonic integrated circuit (PIC) and an electronic integrated circuit (EIC). The PIC may convert an optical signal into an electrical signal, and the EIC may control high frequency signals input/output from the optical integrated circuit.

The semiconductor chip 400 may be located on the photonics chip 300. An electrical signal converted by the photonics chip 300 is input to the semiconductor chip 400, and the semiconductor chip 400 may output an electrical signal to the photonics chip 300.

In some embodiments, the semiconductor chip 400 may include a memory chip, a system on chip (SOC), a logic chip, a power management integrated circuit (PMIC) chip, etc. The memory chips may include DRAM chips, SRAM chips, MRAM chips, and/or NAND flash memory chips. The logic chip may include an application processor (AP), a microprocessor, a central processing unit (CPU), a controller, or an application specific integrated circuit (ASIC).

A plurality of photonics bridge chips 200s may be located on the package substrate 100. Each of the plurality of photonics bridge chips 200s may be located between the plurality of chiplets CL. For example, each of the plurality of photonics bridge chips 200s is located in a space where the plurality of chiplets CL are spaced apart, and thus, a side surface of each of the plurality of photonics bridge chips 200s may face a side surface of the plurality of adjacent chiplets CL. The plurality of photonics bridge chips 200s may transmit optical signals between the plurality of chiplets CL. For example, the plurality of photonics bridge chips 200s may transmit an optical signal from one chiplet among a plurality of adjacent chiplets to another chiplet.

In some embodiments, an area of each of the plurality of photonics bridge chips 200s may be less than an area of each of the plurality of chiplets. For example, the area of each of the plurality of photonics bridge chips 200s may vary depending on the separation distance between the plurality of chiplets CL.

Hereinafter, for convenience of explanation, the plurality of chiplets CL and the plurality of photonics bridge chips 200s are explained in detail using a first chiplet CL1, a second chiplet CL2, and a first photonics bridge chip 200.

The plurality of chiplets CL may include the first chiplet CL1 and the second chiplet CL2. The first chiplet CL1 and the second chiplet CL2 may be spaced apart in the horizontal direction. For example, the first chiplet CL1 may be spaced apart from the second chiplet CL2 in the first horizontal direction (X direction).

The first chiplet CL1 may include a first photonics chip 301 and a first semiconductor chip 401. The first photonics chip 301 may include a first substrate 311, a first waveguide 331, and a first wiring structure 321.

The first substrate 311 of the first photonics chip 301 may include an active surface 311_A and an inactive surface facing the active surface 311_A. The first wiring structure 321 may be formed on the active surface 311_A of the first substrate 311.

The first photonics chip 301 may include a first through via 311_V extending from the inactive surface of the first substrate 311 to the active surface 311_A. The first through via 311_V may be electrically connected to the first wiring structure 321.

The first substrate 311 may include a semiconductor material, such as silicon (Si). Alternatively, the first substrate 311 may include a semiconductor material, such as germanium (Ge).

In some embodiments, a plurality of individual devices that are used to interface a first optical component 341 of the first waveguide 331 with other individual devices may be located on the active surface 311_A of the first substrate 311. For example, the plurality of individual devices may include CMOS drivers, transimpedance amplifiers, etc. to perform functions, such as controlling high-frequency signaling of the first optical component 341.

The first wiring structure 321 may include a first wiring pattern 3211 and a first wiring insulating layer 3212 surrounding the first wiring pattern 3211. The first wiring pattern 3211 may include a first wiring line 3211_L extending in the horizontal direction and a first wiring via 3211_V extending in the vertical direction from the first wiring line 3211_L. The first wiring pattern 3211 may be electrically connected to the plurality of individual devices and the first through via 311_V.

The first waveguide 331 may be located on the upper surface of the active surface 311_A of the first substrate 311. The first waveguide 331 may be a passage for passing an optical signal. For example, the first waveguide 331 may be a passage through which an optical signal input through an optical fiber F passes in the horizontal direction.

In some embodiments, the first wire insulating layer 3212 may surround the first waveguide 331. For example, the first waveguide 331 may be buried inside the first wire insulating layer 3212. However, the present embodiment is not limited thereto, and the first waveguide 331 may be covered with an oxide layer that is different from the first wire insulating layer 3212. For example, the first waveguide 331 may be buried by an oxide layer, and the first optical component 341 may be located inside the oxide layer.

The first waveguide 331 may include the first optical component 341. The first optical component 341 may convert an optical signal into an electrical signal and an electrical signal into an optical signal. In some embodiments, the first optical component 341 may include an optical detector, a laser diode, and a modulator.

In a process of inputting an optical signal to the first chiplet CL1, the optical detector may detect the optical signal input to the first photonics chip 301. The first photonics chip 301 may detect an optical signal input through the optical detector and convert it into an electrical signal. The electrical signal converted by the optical detector may be transmitted to the plurality of individual devices on the active surface 311_A of the first substrate 311 through the first wiring pattern 3211 of the first photonics chip 301.

In a process of outputting an optical signal from the first chiplet CL1, the plurality of individual devices on the active surface 311_A of the first substrate 311 of the first photonics chip 301 may transmit electric signals to the modulator. In response to a received electrical signal, the modulator may convert the electrical signal into an optical signal by inputting a signal into light emitted by the laser diode.

In some embodiments, the first photonics chip 301 may be disposed on the package substrate 100 so that the active surface 311_A of the first substrate 311 faces the first semiconductor chip 401. For example, the first waveguide 331 may be located on an upper surface (i.e., the active surface 311_A) of the first photonics chip 301 and may be spaced apart from the package substrate 100 with the first substrate 311 therebetween.

In some embodiments, the optical fiber F may be attached to the first photonics chip 301. For example, the first photonics chip 301 includes a groove extending inward from a side surface thereof, and the optical fiber F may be located within the groove. In some embodiments, the optical fiber F may be optically connected to the first waveguide 331 of the first photonics chip 301. For example, the optical fiber F and the first waveguide 331 may be optically connected through a grating coupler or an edge coupler.

In some embodiments, the first photonics chip 301 may further include an upper pad 381. The upper pad 381 is disposed on the upper surface of the first photonics chip 301 and may be electrically connected to the first wiring pattern 3211.

In some embodiments, the first photonics chip 301 may further include a lower pad 371. The lower pad 371 may be disposed on a lower surface of the first photonics chip 301 and may be electrically connected to the first through via 311_V.

In some embodiments, the lower pad 371 of the first photonics chip 301 may be electrically connected to the upper pad 180 of the package substrate 100 through an adhesive film 150. For example, the adhesive film 150 may be an anisotropic conductive film (ACF) or a non-conductive film (NCF).

However, the present embodiment is not limited thereto, and the first photonics chip 301 and the package substrate 100 may be electrically connected through solder ball attach, direct bonding, or hybrid bonding. In instances, an encapsulating material, such as underfill may be positioned between the first photonics chip 301 and the package substrate 100.

The first semiconductor chip 401 may include an active surface and an inactive surface facing the active surface. In some embodiments, the first semiconductor chip 401 may be positioned on the first photonics chip 301 so that the active surface of the first semiconductor chip 401 faces downward. For example, the first semiconductor chip 401 may be positioned on the first photonics chip 301 in a face-down manner.

In some embodiments, a plurality of various types of individual devices may be located on the active surface of the first semiconductor chip 401. For example, the plurality of individual devices may include various microelectronic devices, for example, an image sensor, such as a complementary metal-oxide semiconductor transistor (CMOS transistor), a metal-oxide-semiconductor filed effect transistor (MOSFET), a large scale integration (LSI), a CMOS imaging sensor (CIS), a micro-electro-mechanical system (MEMS), an active device, and a passive device, etc.

In some embodiments, the first semiconductor chip 401 may further include a lower pad 471. The lower pad 471 is disposed on a lower surface of the first semiconductor chip 401 and may be electrically connected to a plurality of individual devices of the first semiconductor chip 401.

The upper pad 381 of the first photonics chip 301 and the lower pad 471 of the first semiconductor chip 401 may be electrically connected by a connection terminal CT41. However, embodiments are not limited thereto, and the upper pad 381 of the first photonics chip 301 and the lower pad 471 of the first semiconductor chip 401 may be electrically connected by an anisotropic conductive film, a non-conductive film, direct bonding, or hybrid bonding.

The second chiplet CL2 may include a second photonics chip 302 and a second semiconductor chip 402. The second photonics chip 302 may include a second substrate 312, a second waveguide 332, and a second wiring structure 322. In some embodiments, the components and materials of the second chiplet CL2 and the first chiplet CL1 may be substantially the same.

The second substrate 312 of the second photonics chip 302 may include an active surface 312_A and an inactive surface facing the active surface 312_A. The second wiring structure 322 may be formed on the active surface 312_A of the second substrate 312.

The second photonics chip 302 may include a second through via 312_V extending from the inactive surface of the second substrate 312 to the active surface 312_A. The second through via 312_V may be electrically connected to the second wiring structure 322.

The second substrate 312 may include a semiconductor material, such as silicon (Si). Alternatively, the second substrate 312 may include a semiconductor material, such as germanium (Ge).

The second wiring structure 322 may be located on the active surface 312_A of the second substrate 312. The second wiring structure 322 may include a second wiring pattern 3221 and a second wiring insulating layer 3222 surrounding the second wiring pattern 3221. The second wiring pattern 3221 may include a second wiring line 3221_L extending in the horizontal direction and a second wiring via 3221_V extending in the vertical direction from the second wiring line 3221_L. The second wiring pattern 3221 may be electrically connected to the plurality of individual devices and the second through via 312_V.

The second waveguide 332 may be located on the active surface 312_A of the second substrate 312. The second waveguide 332 may be a passage for passing an optical signal. For example, the second waveguide 332 may be a passage through which an optical signal input through the optical fiber F passes in the horizontal direction.

In some embodiments, the second wire insulation layer 3222 may surround the second waveguide 332. For example, the second waveguide 332 may be buried inside the second wire insulating layer 3222. However, the present embodiment is not limited to this, and the second waveguide 332 may be covered with an oxide layer that is different from the second wire insulating layer 3222. For example, the second waveguide 332 may be buried by an oxide layer, and a second optical component 342 may be located inside the oxide layer.

The second waveguide 332 may include the second optical component 342. The second optical component 342 may convert optical signals into electrical signals and convert electrical signals into optical signals. In some embodiments, the second optical component 342 may include an optical detector, a laser diode, and a modulator. For example, the operation of each component of the second optical component 342 may be substantially the same as that of the first optical component 341 described above.

In some embodiments, the second photonics chip 302 may be disposed on the package substrate 100 so that the active surface 312_A of the second substrate 312 faces the second semiconductor chip 402. For example, the second waveguide 332 may be located on an upper surface of the second photonics chip 302 and may be spaced apart from the package substrate 100 with the second substrate 312 therebetween.

In some embodiments, the optical fiber F may be attached to second photonics chip 302. For example, the second photonics chip 302 includes a groove extending inward from a side surface thereof, and the optical fiber F may be located within the groove. In some embodiments, the optical fiber F may be optically connected to the second waveguide 332 of the second photonics chip 302. For example, the optical fiber F and the second waveguide 332 may be optically connected through a grating coupler or an edge coupler.

In some embodiments, the second photonics chip 302 may further include an upper pad 382. The upper pad 382 is disposed on the upper surface of the second photonics chip 302 and may be electrically connected to the second wiring pattern 3221.

In some embodiments, the second photonics chip 302 may further include a lower pad 372. The lower pad 372 is disposed on a lower surface of the second photonics chip 302 and may be electrically connected to the second through via 312_V.

In some embodiments, the lower pad 372 of the second photonics chip 302 may be electrically connected to the upper pad 180 of the package substrate 100 through the adhesive film 150. For example, the adhesive film 150 may be an anisotropic conductive film (ACF) or a non-conductive film (NCF).

The second semiconductor chip 402 may include an active surface and an inactive surface facing the active surface. In some embodiments, the second semiconductor chip 402 may be positioned on the second photonics chip 302 so that the active surface of the second semiconductor chip 402 faces downward. For example, the second semiconductor chip 402 may be positioned on the second photonics chip 302 in a face-down manner.

In some embodiments, the first semiconductor chip 401 and the second semiconductor chip 402 may be different types of semiconductor chips. For example, the first semiconductor chip 401 may be a logic chip, and the second semiconductor chip 402 may be a memory chip. However, the present embodiment is not limited thereto, and the first semiconductor chip 401 and the second semiconductor chip 402 may be the same type of semiconductor chip.

In some embodiments, the second semiconductor chip 402 may further include a lower pad 472. The lower pad 472 is disposed on a lower surface of the second semiconductor chip 402 and may be electrically connected to the plurality of individual devices of the second semiconductor chip 402.

The upper pad 382 of the second photonics chip 302 and the lower pad 472 of the second semiconductor chip 402 may be electrically connected by a connection terminal CT42. However, embodiments are not limited thereto, and the upper pad 382 of the second photonics chip 302 and the lower pad 472 of the second semiconductor chip 402 may be electrically connected by an anisotropic conductive film, a non-conductive film, direct bonding, or hybrid bonding.

The first photonics bridge chip 200 may be located between the first chiplet CL1 and the second chiplet CL2. For example, the first chiplet CL1 may be spaced apart from the second chiplet CL2 in the first horizontal direction (X direction) with the first photonics bridge chip 200 therebetween. For example, the first photonics bridge chip 200 may be located between the first photonics chip 301 and the second photonics chip 302.

For example, among side surfaces of the first photonics bridge chip 200, a first side surface and a second side surface spaced apart from each other in the first horizontal direction may face the first chiplet CL1 and the second chiplet CL2, respectively. Specifically, the first side surface of the first photonics bridge chip 200 faces one side surface of the first photonics chip 301 of the first chiplet CL1, and the second side surface faces one side surface of the second photonics chip 302 of the second chiplet CL2.

The first photonics bridge chip 200 may include a bridge substrate 210, a bridge wiring structure 220, and a plurality of waveguide patterns 230.

The bridge substrate 210 may include a semiconductor material, such as silicon (Si). Alternatively, the bridge substrate 210 may include a semiconductor material, such as germanium (Ge).

In some embodiments, a plurality of individual devices may be located on an upper surface of the bridge substrate 210. The plurality of individual devices may be used to adjust the optical connection between the plurality of waveguide patterns 230 on the bridge substrate 210. For example, the plurality of individual devices may be used to adjust the optical connection between a bridge waveguide 230_B and a test waveguide 230_T. That is, the test waveguide 230_T may be selectively connected to the bridge waveguide 230_B through the plurality of individual devices.

The bridge wiring structure 220 may be formed on an upper surface of the bridge substrate 210. A bridge through-via 210_V may penetrate the bridge substrate 210. In some embodiments, the bridge through-via 210_V may be electrically connected to the bridge wiring structure 220 and/or a plurality of individual devices on an active surface of the bridge substrate 210.

The first photonics bridge chip 200 may further include a lower pad 270 located on a lower surface of the bridge substrate 210. The lower pad 270 may be electrically connected to the bridge through-via 210_V. The lower pad 270 of the first photonics bridge chip 200 may be electrically connected to the upper pad 180 of the package substrate 100 by the adhesive film 150. However, the method of electrically connecting the lower pad 270 of the first photonics bridge chip 200 to the upper pad 180 of the package substrate 100 is not limited thereto.

The bridge wiring structure 220 may include a bridge wiring pattern 221 and a bridge insulating layer 222 surrounding the bridge wiring pattern 221. The bridge wiring pattern 221 may include a bridge wiring line 221_P extending in a horizontal direction and a bridge wiring via 221_V extending in a vertical direction from the bridge wiring line 221_P. The bridge wiring pattern 221 may be electrically connected to the plurality of individual devices and the bridge through-via 210_V.

The plurality of waveguide patterns 230 may be located on an upper surface of the bridge substrate 210. The plurality of waveguide patterns 230 may be buried within the first photonics bridge chip 200. For example, the plurality of waveguide patterns 230 may be buried within the bridge insulating layer 222. However, the present embodiment is not limited thereto, and the plurality of waveguide patterns 230 may be covered with an oxide layer that is different from the bridge insulating layer 222. For example, the plurality of waveguide patterns 230 may be silicon waveguides.

The plurality of waveguide patterns 230 may include a bridge waveguide 230_B and a test waveguide 230_T. In some embodiments, the bridge waveguide 230_B may be a passage through which an optical signal passes from the first photonics chip 301 to the second photonics chip 302, and the test waveguide 230_T may be a passage through which an optical signal passes when testing whether the first photonics bridge chip 200 is coupled to the first photonics chip 301 and the second photonics chip 302.

In some embodiments, the bridge waveguide 230_B and the test waveguide 230_T may be at the same vertical level as each other. For example, the bridge waveguide 230_B and the test waveguide 230_T may be formed through the same process, and thus, the vertical levels of the bridge waveguide 230_B and the test waveguide 230_T may be the same. In the present specification, “vertical level” refers to a distance separated from a lower surface of the package substrate 100.

Referring to FIGS. 3 and 4, in some embodiments, the vertical level of the bridge waveguide 230_B may be the same as the vertical level of the first waveguide 331 of the first photonics chip 301 and the vertical level of the second waveguide 332 of the second photonics chip 302. One end of the bridge waveguide 230_B may face the first waveguide 331, and the other end of the bridge waveguide 230_B may face the second waveguide 332. For example, the bridge waveguide 230_B may be optically connected to the first waveguide 331 and the second waveguide 332 through an edge coupler.

In some embodiments, the test waveguide 230_T may not be optically connected to the first waveguide 331 and the second waveguide 332. For example, both ends of the test waveguide 230_T may be located within the bridge insulating layer 222 and may not be exposed to the outside.

Referring to FIG. 4, the test waveguide 230_T may be optically connected to the bridge waveguide 230_B. For example, the test waveguide 230_T and the bridge waveguide 230_B may be optically connected through a tunable coupler. The tunable coupler may be configured to transmit optical signals between waveguides separated in the horizontal direction.

In some embodiments, the test waveguide 230_T may receive an optical signal from the bridge waveguide 230_B. For example, an optical signal transmitted from the first waveguide 331 or the second waveguide 332 to the bridge waveguide 230_B. may be branched and transmitted to the test waveguide 230_T.

The bridge waveguide 230_B may include a first tunable coupler TC_B, and the test waveguide 230_T may include a second tunable coupler TC_T. The first tunable coupler TC_B may be a region of the bridge waveguide 230_B where a groove is formed, and the second tunable coupler TC_T may be a region of the test waveguide 230_T where a groove is formed. The first tunable coupler TC_B and the second tunable coupler TC_T face each other, but may be spaced apart in the horizontal direction. An optical signal may be transmitted from the first tunable coupler TC_B to the second tunable coupler TC_T.

Referring to FIGS. 4 and 5, the first photonics bridge chip 200 may include a groove G_200 that is recessed from an upper surface of the first photonics bridge chip 200 toward an inside thereof. For example, the groove G_200 may be formed in the bridge insulating layer 222. The groove G_200 may be recessed until the plurality of waveguide patterns 230 are exposed to the outside. In some embodiments, groove G_200 may be located on top of test waveguide 230_T. For example, a portion of the test waveguide 230_T may be exposed to the outside by the groove G_200.

In some embodiments, a probe pin of a test device may be inserted into the groove G_200 and connected to the test waveguide 230_T. For example, the probe pin may receive an optical signal as an optical probe pin. For example, the probe pin may be optically connected to the test waveguide 230_T and may receive an optical signal flowing in the test waveguide 230_T. In some embodiments, the test device may include a device configured to convert an optical signal received through a probe pin into an electrical signal and an observation device such as an oscilloscope that may observe the electrical signal.

In some embodiments, test waveguide 230_T may further include a grating coupler GT_T. The grating coupler GT_T may be a region of the test waveguide 230_T that includes a downwardly recessed groove. The grating coupler GT_T may be located in a region where the test waveguide 230_T is exposed to the outside. For example, the grid coupler GT_T may be located inside the groove G_200.

In other words, the grating coupler GT_T may be located in a region of the test waveguide 230_T exposed by the groove G_200. For example, the downwardly recessed groove of the test waveguide 230_T may be located in the region exposed by the groove G_200.

For example, the probe pin and the test waveguide 230_T may be optically connected through the grating coupler GT_T. Accordingly, a connection between the probe pin and the test waveguide 230_T may be relatively easily made.

The test waveguide 230_T may be used when the connection status of the first photonics bridge chip 200 with the first photonics chip 301 and the second photonics chip 302 is tested by receiving an optical signal from the bridge waveguide 230_B.

For example, when the first photonics bridge chip 200 transmits an optical signal from the first photonics chip 301 to the second photonics chip 302, a portion of the optical signal transmitted from the first waveguide 331 to the bridge waveguide 230_B may be transmitted to the test waveguide 230_T through a tunable coupler. A probe pin of an externally installed test device connected to the test waveguide 230_T, may receive the optical signal from the test waveguide 230_T, and may determine the coupling state of the first waveguide 331 and/or the second waveguide 332 with the bridge waveguide 230_B.

However, the test waveguide 230_T is not limited thereto, and, in some embodiments, the test waveguide 230_T may include an optical detector electrically connected to the bridge wiring structure 220. The optical detector may convert the optical signal transmitted to the test waveguide 230_T into an electrical signal and transmit the electrical signal through the connected bridge wiring structure 220. The probe pin may be connected to the bridge wiring structure 220 that is electrically connected to the optical detector of the test waveguide 230_T.

In some embodiments, an area of the first photonics bridge chip 200 may be less than a region of each of the first photonics chip 301 and the second photonics chip 302. For example, a length of the first photonics bridge chip 200 in the first horizontal direction (X direction) may be less than a length of each of the first photonics chip 301 and the second photonics chip 302 in the first horizontal direction (X direction). However, a length of the first photonics bridge chip 200 in the second horizontal direction (Y direction) may be substantially equal to a length of each of the first photonics chip 301 and the second photonics chip in the second horizontal direction (Y direction).

Each of the plurality of chiplets CL of the semiconductor package 1000 may have one semiconductor chip 400 mounted on one photonics chip 300. The photonics chips 300 of a plurality of chiplets CL may transmit and receive optical signals to each other through a plurality of photonics bridge chips 200s. Accordingly, because the photonics chip 300 may be miniaturized, the yield of the photonics chip 300 may be improved.

Each of the plurality of photonics bridge chips 200 of the semiconductor package 1000 includes the test waveguide 230_T, thus, it is easy to check the respective coupling between the plurality of photonics chip 300 and the plurality of photonics bridge chips 200s.

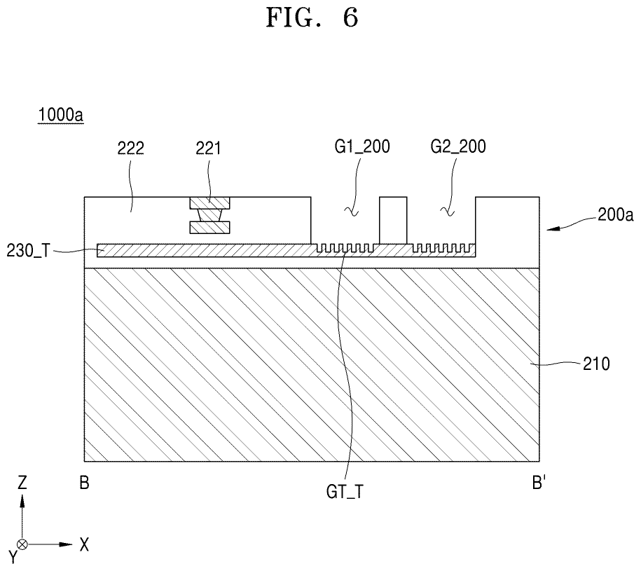

FIG. 6 is a schematic cross-sectional view of a semiconductor package 1000a taken along a line the same as the line B-B′ of the semiconductor package 1000 of FIG. 4, according to an embodiment.

Most of the components constituting the semiconductor package 1000a described below and the materials included in the components are substantially the same or similar to those previously described with reference to FIG. 1. Therefore, for convenience of explanation, the description will mainly focus on differences between the semiconductor package 1000a of FIG. 6 and the semiconductor package 1000 of FIG. 1 described above.

The first photonics bridge chip 200a of the semiconductor package 1000a may include a plurality of grooves that are recessed from an upper surface to an inside of the first photonics bridge chip 200a. For example, the first photonics bridge chip 200a may include a first groove G1_200 and a second groove G2_200.

The first groove G1_200 and the second groove G2_200 may be located on top of the test waveguide 230_T. For example, portions (i.e., a first portion and a second portion) of the test waveguide 230_T may be respectively exposed to the outside by the first groove G1_200 and the second groove G2_200.

In some embodiments, test waveguide 230_T may include a grating coupler GT_T. The grating coupler GT_T may be located in a region of the test waveguide 230_T exposed by the first groove G1_200 and the second groove G2_200.

Probe pins different from each other may be inserted into the first groove G1_200 and the second groove G2_200 of the first photonics bridge chip 200a. For example, the probe pin inserted into the first groove G1_200 may be connected to a test device configured to measure coupling between the first photonics bridge chip 200a and other photonics chip 300 (refer to FIG. 1). The probe pin inserted into the second groove G2_200 may measure an amount of an optical signal lost when the optical signal is transmitted to the first photonics bridge chip 200a. For example, different test devices may be connected to the test waveguide 230_T through the first groove G1_200 and the second groove G2_200.

In some embodiments, a width of the first groove G1_200 and a width of the second groove G2_200 may be different. For example, the width of the first groove G1_200 and the width of the second groove G2_200 may vary depending on a width of the probe pin of the test device.

The first photonics bridge chip 200a of the semiconductor package 1000a may perform multiple tests simultaneously, and thus, a time required for testing the semiconductor package 1000a may be reduced. In addition, by forming a size of the groove to match to the test device (e.g., a probe pin of the test device), the test waveguide 230_T may be protected from the outside and the movement of the probe pin during testing may be suppressed.

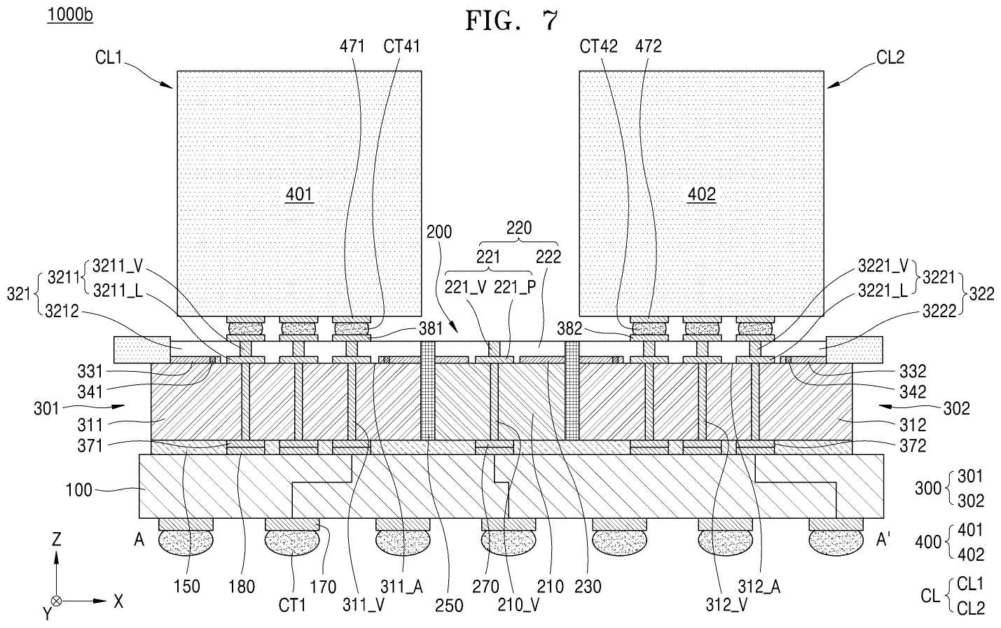

FIG. 7 is a schematic cross-sectional view of a semiconductor package 1000b taken along a line the same as the line A-A′ of FIG. 1, according to an embodiment.

Most of the components constituting the semiconductor package 1000b described below and the materials included in the components are substantially the same or similar to those previously described with reference to FIG. 1. Therefore, for convenience of explanation, the description will mainly focus on differences between the semiconductor package 1000b of FIG. 7 and the semiconductor package 1000 of FIG. 1 described above.

Referring to FIG. 7 and FIG. 1 together, the semiconductor package 1000b may further include a transparent encapsulant 250. The transparent encapsulant 250 is located on the package substrate 100 and may be located between the photonics chip 300 of each of the plurality of chiplets CL and the plurality of photonics bridge chips 200s. For example, the transparent encapsulant 250 may fill a space between the photonics chip 300 of each of the plurality of chiplets CL and the plurality of photonics bridge chips 200s.

In some embodiments, an upper surface of the transparent encapsulant 250 and upper surfaces of the plurality of photonics bridge chips 200s may be coplanar. For example, the upper surface of the transparent encapsulant 250, the upper surface of the photonics chip 300, and the upper surfaces of the plurality of photonics bridge chips 200s may be coplanar. In other words, the vertical level of the upper surface of the transparent encapsulant 250, the vertical level of each upper surface of the plurality of photonics bridge chips 200s, and the vertical level of the upper surface of the photonics chip 300 may be substantially the same.

In some embodiments, in the process of manufacturing the semiconductor package 1000b, after mounting the photonics chip 300 and the plurality of photonics bridge chips 200s on the package substrate 100, the transparent encapsulant 250 may be formed to fill recesses between the photonics chip 300 and the plurality of photonics bridge chips 200s, and to cover the photonics chip 300 and the plurality of photonics bridge chips 200s. Thereafter, in a process of removing an upper part of the transparent encapsulant 250, the upper surface of the transparent encapsulant 250, the upper surface of the photonics chip 300, and the upper surfaces of the plurality of photonics bridge chips 200s may be coplanar.

In some embodiments, the transparent encapsulant 250 may have a refractive index lower than that of silicon. For example, the refractive index of the transparent encapsulant 250 may be in a range from about 0.5 to about 1.0.

The transparent encapsulant 250 of the semiconductor package 1000b is located between the plurality of photonics bridge chips 200s and the photonics chip 300, and thus, side surfaces of the plurality of photonics bridge chips 200s and a side surface of the photonics chip 300 may be protected from the outside. In addition, the transparent encapsulant 250 may maintain a constant refractive index between the photonics chip 300 and the plurality of photonics bridge chips 200s, thereby improving the accuracy of the optical signal.

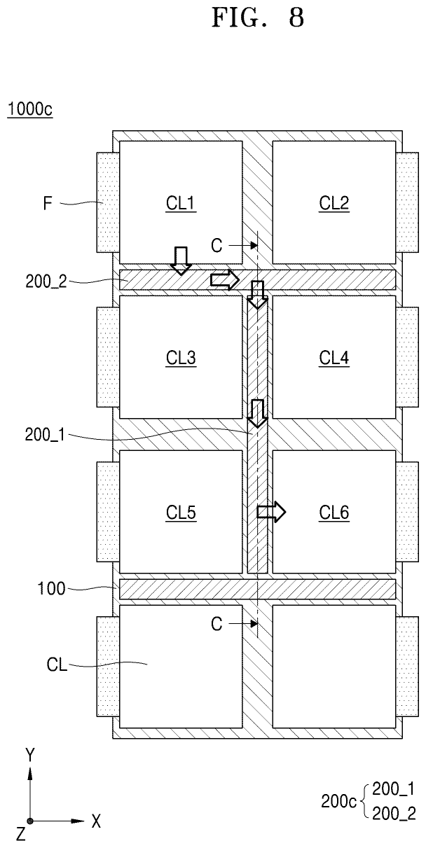

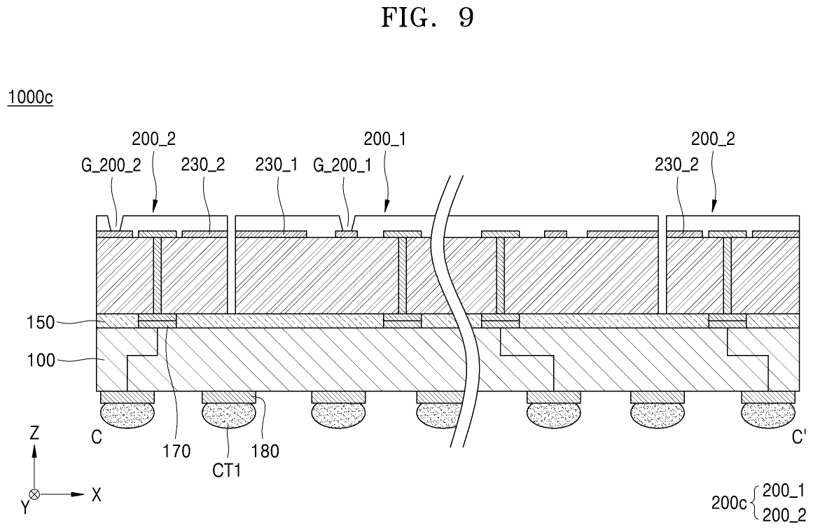

FIG. 8 is a schematic plan view of a semiconductor package 1000c according to an embodiment. FIG. 9 is a schematic cross-sectional view taken along line C-C′ of the semiconductor package 1000c of FIG. 8.

Most of the components constituting the semiconductor package 1000c described below and the materials included in the components are substantially the same or similar to those previously described with reference to FIG. 1. Therefore, for convenience of explanation, the description will mainly focus on differences between the semiconductor package 1000c of FIG. 8 and the semiconductor package 1000 of FIG. 1 described above.

The semiconductor package 1000c may include a plurality of chiplets CL and a plurality of photonics bridge chips 200c. The plurality of chiplets CL may be spaced apart in at least one of the first horizontal direction (X direction) and the second horizontal direction (Y direction) and arranged in a matrix. The plurality of photonics bridge chips 200c may be located between a plurality of chiplets CL.

The plurality of chiplets CL may include first to sixth chiplets CL1, CL2, CL3, CL4, CL5, and CL6. The first chiplet CL1 may be spaced apart from the second chiplet CL2 in the first horizontal direction (X direction), the third chiplet CL3 may be spaced apart from the fourth chiplet CL4 in the first horizontal direction (X direction), and the fifth chiplet CL5 may be spaced apart from the sixth chiplet CL6 in the first horizontal direction (X direction). The first chiplet CL1, the third chiplet CL3, and the fifth chiplet CL5 may be spaced apart from each other in the second horizontal direction (Y direction), and the second chiplet CL2, the fourth chiplet CL4, and the sixth chiplet CL6 may be spaced apart from each other in the second horizontal direction (Y direction).

In some embodiments, each of the plurality of photonics bridge chips 200c may be located between at least two chiplets. For example, a plurality of photonics bridge chips 200c may be located between four chiplets. For example, one of the plurality of photonics bridge chips 200c may be located between the first to fourth chiplets CL1, CL2, CL3, and CL4, and may transmit and receive optical signals with the first to fourth chiplets CL1, CL2, CL3, and CL4.

The plurality of photonics bridge chips 200c may include a first photonics bridge chip 200_1 and a second photonics bridge chip 200_2. The first photonics bridge chip 200_1 may be located between chiplets spaced apart in the first horizontal direction (X direction). The second photonics bridge chip 200_2 may be located between chiplets spaced apart in the second horizontal direction (Y direction).

For example, the first photonics bridge chip 200_1 may be located in a space between the third chiplet CL3 and the fourth chiplet CL4, and a space between the fifth chiplet CL5 and the sixth chiplet CL6. The second photonics bridge chip 200_2 may be located in a space between the first chiplet CL1 and the third chiplet CL3 and a space between the second chiplet CL2 and the fourth chiplet CL4.

One side surface of the first photonics bridge chip 200_1 may face one side surface of the second photonics bridge chip 200_2. For example, one end of the first plurality of waveguide patterns 230_1 of the first photonics bridge chip 200_1 may face one end of the second plurality of waveguide patterns 230_2 of the second photonics bridge chip 200_2. Specifically, one end of the first bridge waveguide of the first plurality of waveguide patterns 230_1 may face one end of the second bridge waveguide of the second plurality of waveguide patterns 230_2.

The first plurality of waveguide patterns 230_1 of the first photonics bridge chip 200_1 and the second plurality of waveguide patterns 230_2 of the second photonics bridge chip 200_2 may have the same vertical level. Specifically, the vertical level of the first bridge waveguide of the first plurality of waveguide patterns 230_1 may be the same as the vertical level of the second bridge waveguide of the second plurality of waveguide patterns 230_2.

An optical signal may be transmitted from the first bridge waveguide of the first plurality of waveguide patterns 230_1 to the second bridge waveguide of the second plurality of waveguide patterns 230_2. The first bridge waveguide of the first plurality of waveguide patterns 230_1 and the second bridge waveguide of the second plurality of waveguide patterns 230_2 may be optically connected through an edge coupler.

In some embodiments, the first photonics bridge chip 200_1 may include a first groove G_200_1 that is recessed from an upper surface to an inside thereof. The first groove G_200_1 may be located on top of a first test waveguide of the first plurality of waveguide patterns 230_1 of the first photonics bridge chip 200_1. For example, the first test waveguide may be exposed to the outside through the first groove G_200_1. A coupling state between the first photonics bridge chip 200_1 and another chip may be tested by exposing the first test waveguide connected to the first bridge waveguide with a tunable coupler.

The second photonics bridge chip 200_2 may include a second groove G_200_2 that is recessed from an upper surface to an inside thereof. The second groove G_200_2 may be located on top of a second test waveguide of the second plurality of waveguide patterns 230_2 of the second photonics bridge chip 200_2. The second test waveguide may be exposed to the outside by the second groove G_200_2. A coupling state between the second photonics bridge chip 200_2 and another chip may be tested by exposing the second test waveguide connected to the second bridge waveguide with a tunable coupler.

As the plurality of photonics bridge chips 200c of the semiconductor package 1000c are optically connected to each other, a phenomenon of losing optical signals due to coupling in a process of transmitting and receiving the optical signals between chiplets located at a relatively long distance may be suppressed. For example, in a process of moving an optical signal from the first chiplet CL1 to the sixth chiplet CL6, the optical signal output from the first chiplet CL1 may be transmitted to the second photonics bridge chip 200_2, may be transmitted to the first photonics bridge chip 200_1 from the second photonics bridge chip 200_2, and may be input to the sixth chiplet CL6 from the first photonics bridge chip 200_1.

While aspects of the inventive concept have been particularly shown and described with reference to embodiments thereof, it will be understood that various changes in form and details may be made therein without departing from the spirit and scope of the following claims.

What is claimed is:

1. A semiconductor package comprising:
a package substrate;
a plurality of chiplets located on the package substrate, the plurality of chiplets including a photonics chip and a semiconductor chip located on the photonics chip; and
a plurality of photonics bridge chips located on the package substrate,
wherein the plurality of chiplets are spaced apart from each other in a horizontal direction, and
each of the plurality of photonics bridge chips is located between the plurality of chiplets.

2. The semiconductor package of claim 1, wherein
the plurality of chiplets include a first chiplet and a second chiplet,
the first chiplet includes a first photonics chip and a first semiconductor chip,
the second chiplet includes a second photonics chip and a second semiconductor chip, and
the plurality of photonics bridge chips include a first photonics bridge chip located between the second photonics chip and the first photonics chip.

3. The semiconductor package of claim 2, wherein
the photonics chip and the semiconductor chip of each of the plurality of chiplets are in a one-to-one correspondence,
the first photonics chip includes an active surface and an inactive surface facing the active surface,
the second photonics chip includes an active surface and an inactive surface facing the active surface,
the active surface of the first photonics chip faces the first semiconductor chip, and
the active surface of the second photonics chip faces the second semiconductor chip.

4. The semiconductor package of claim 3, wherein
the first photonics chip includes a first waveguide located on the active surface of the first photonics chip,
the second photonics chip includes a second waveguide located on the active surface of the second photonics chip,
the first photonics bridge chip includes a first bridge waveguide buried therein, and
vertical levels of the first waveguide, the second waveguide, and the first bridge waveguide are same.

5. The semiconductor package of claim 4, wherein
one end of the first bridge waveguide faces one end of the first waveguide, and
another end of the first bridge waveguide faces one end of the second waveguide.

6. The semiconductor package of claim 1, further comprising:
a transparent encapsulant located between the plurality of photonics chips and the plurality of photonics bridge chips.

7. The semiconductor package of claim 6, wherein the transparent encapsulant has a refractive index less than a refractive index of silicone.

8. The semiconductor package of claim 1, wherein
each of the plurality of photonics bridge chips includes a bridge waveguide and a test waveguide that are disposed at the same vertical level and are spaced apart in the horizontal direction,
wherein the test waveguide is configured to receive an optical signal from the bridge waveguide.

9. The semiconductor package of claim 8, wherein
each of the bridge waveguide and the test waveguide includes a tunable coupler, and
the tunable coupler of the bridge waveguide and the tunable coupler of the test waveguide face each other.

10. The semiconductor package of claim 8, wherein
each of the plurality of photonics bridge chips includes a groove recessed from an upper surface to an inside thereof, and
the test waveguide is partially exposed to outside by the groove.

11. The semiconductor package of claim 10, wherein
the test waveguide further includes a grating coupler, and
the grating coupler is located in a region exposed by the groove.

12. The semiconductor package of claim 1, further comprising:
an optical fiber,
wherein the optical fiber is attached to the photonics chip of at least some of the plurality of chiplets.

13. The semiconductor package of claim 1, wherein an area of each of the plurality of photonics bridge chips is less than an area of each photonics chip of the plurality of chiplets.

14. A semiconductor package comprising:
a package substrate;
a plurality of chiplets located on the package substrate, the plurality of chiplets including a photonics chip and a semiconductor chip located on the photonics chip; and
a plurality of photonics bridge chips located on the package substrate and each including a bridge waveguide and a test waveguide disposed at the same vertical level,
wherein the plurality of chiplets are spaced apart in a horizontal direction,
each of the plurality of photonics bridge chips is located between the plurality of chiplets, and
the bridge waveguides of at least some of the plurality of photonics bridge chips face the bridge waveguides of other photonics bridge chips.

15. The semiconductor package of claim 14, wherein
the plurality of chiplets are spaced apart in at least one of a first horizontal direction and a second horizontal direction perpendicular to the first horizontal direction,
the plurality of photonics bridge chips include a first photonics bridge chip and a second photonics bridge chip,
the first photonics bridge chip is located between the plurality of chiplets spaced apart in the first horizontal direction, and
the second photonics bridge chip is located between the plurality of chiplets spaced apart in the second horizontal direction.

16. The semiconductor package of claim 15, wherein
a horizontal level of the bridge waveguide of the plurality of photonic bridge chips is the same as a horizontal level of the waveguide of the photonics chip of each of the plurality of chiplets, and
one end of a first bridge waveguide of the first photonics bridge chip and one end of a second bridge waveguide of the second photonics bridge chip face each other.

17. The semiconductor package of claim 15, wherein
the first photonics bridge chip includes a first bridge waveguide and a first test waveguide optically connected to the first bridge waveguide through a tunable coupler, and
the second photonics bridge chip includes a second bridge waveguide and a second test waveguide optically connected to the second bridge waveguide through a tunable coupler.

18. The semiconductor package of claim 17, wherein
the first photonics bridge chip includes a first groove recessed from an upper surface to an inside thereof,
at least a portion of the first test waveguide is exposed to the outside by the first groove,
the second photonics bridge chip includes a second groove recessed from an upper surface to an inside thereof, and
at least a portion of the second test waveguide is exposed to the outside by the second groove.

19. A semiconductor package comprising:
a package substrate;
an external connection terminal located at a bottom of the package substrate;
a plurality of chiplets located on the package substrate, the plurality of chiplets including a photonics chip and a semiconductor chip located on the photonics chip;
a plurality of photonics bridge chips located on the package substrate and each including a bridge waveguide and a test waveguide disposed at the same vertical level; and
a transparent encapsulant located between the plurality of chiplets and the plurality of photonics bridge chips,
wherein the plurality of chiplets are spaced apart from each other in a horizontal direction,
each of the plurality of photonics bridge chips is located between the plurality of chiplets, and
the bridge waveguide and the test waveguide are optically connected through a tunable coupler.

20. The semiconductor package of claim 19, wherein
each of the plurality of photonics bridge chips includes a groove extending inward from an upper surface thereof,
one end of the bridge waveguide of each of the plurality of photonics bridge chips faces at least one of one end of the bridge waveguide of other photonics bridge chip and one end of the waveguide of the photonics chip of the plurality of chiplets, and
a portion of the test waveguide is exposed to the outside by the groove.
